(19) United States
(12) Patent Application Publication
(10) Pub. No.: US 2026/0129933 A1
(43) Pub. Date: May 7, 2026

(54) CHEMICAL VAPOR DEPOSITION PROCESS AND COATING

(71) Applicant: SILCOTEK CORP., Bellefonte, PA (US)

(72) Inventors: Nikolis Austin SNYDER, Bellefonte, PA (US); David A. SMITH, Bellefonte, PA (US); Lucas D. PATTERSON, Altoona, PA (US); James B. MATTZELA, Port Matilda, PA (US)

(21) Appl. No.: 18/686,127

(22) PCT Filed: Aug. 18, 2022
(86) PCT No.: PCT/US2022/040763

§ 371 Date: Feb. 23, 2024

Related U.S. Application Data
(60) Provisional application No. 63/236,413, filed on Aug. 24, 2021.

(51) Int. Cl. H10D 62/834; C23C 16/30

(52) U.S. Cl. CPC H10D 62/834; C23C 16/30

(57) ABSTRACT

Coated articles, systems incorporating the coated articles, and processes of applying the coating to form the coated articles are disclosed. The coated article a substrate and a coating on the substrate. The coating includes silicon, carbon, and hydrogen. A post-exposure water contact angle of the coating, after being exposed to ultrasonic agitation using an aqueous solution of a caustic salt, remains above 80 degrees, remains greater than 60% of a pre-exposure water contact angle, or both.

### PRIORITY

The present application is an international patent cooperation treaty patent application claiming priority and benefit of U.S. Provisional Patent Application No. 63/236,413, entitled “CHEMICAL VAPOR DEPOSITION PROCESS AND COATING,” and filed on Aug. 24, 2021, the entirety of which is incorporated by reference.

### FIELD OF THE INVENTION

The present invention is directed to coated articles, systems including coated articles, and processes of coating to produce a coated article. More particularly, the present invention is directed to coatings containing silicon, carbon, and hydrogen.

### BACKGROUND OF THE INVENTION

Coatings are often susceptible to attack from caustic salts, such and sodium hydroxide or potassium hydroxide. Such attacks reduce hydrophobicity, cause dissolution or physical degradation, or other drawbacks. An example is described in U.S. Pat. No. 9,340,880, directed to a “Semiconductor Fabrication Process,” the entirety of which is incorporated by reference. In the coating of the Semiconductor Fabrication Process, the coating has the drawback of not being resistant to a 20-minute cleaning cycle in an aqueous solution of 5-10% NaOH, by weight/volume, at elevated temperature (79.44° C.) with ultrasonic agitation

Coatings that show one or more improvements in comparison to the prior art would be desirable in the art.

### BRIEF DESCRIPTION OF THE INVENTION

In an embodiment, a coated article includes a substrate and a coating on the substrate. The coating includes silicon, carbon, and hydrogen. A post-exposure water contact angle of the coating, after being exposed to ultrasonic agitation using an aqueous solution of a caustic salt, remains above 80 degrees, remains greater than 60% of a pre-exposure water contact angle, or both.

In another embodiment, a system includes a coated article. The coated article includes a substrate and a coating on the substrate. The coating includes silicon, carbon, and hydrogen. A post-exposure water contact angle of the coating, after being exposed to ultrasonic agitation using an aqueous solution of a caustic salt, remains above 80 degrees, remains greater than 60% of a pre-exposure water contact angle, or both.

In another embodiment, a process includes applying a coating to the coated article. The coated article includes a substrate and a coating on the substrate. The coating includes silicon, carbon, and hydrogen. A post-exposure water contact angle of the coating, after being exposed to ultrasonic agitation using an aqueous solution of a caustic salt, remains above 80 degrees, remains greater than 60% of a pre-exposure water contact angle, or both.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 is a FT-IR plot, according to a comparative example of the disclosure consistent with the first example.

FIG. 2 is a FT-IR plot, according to a comparative example of the disclosure consistent with the second example.

FIG. 3 is a FT-IR plot, according to an embodiment of the disclosure consistent with the third example.

FIG. 4 is a FT-IR plot, according to an embodiment of the disclosure consistent with the fourth example.

FIG. 5 is a FT-IR plot, according to a comparative example of the disclosure consistent with the fifth example.

FIG. 6 is an exemplary system containing an exemplary coated article, according to an embodiment of the disclosure.

Wherever possible, the same reference numbers will be used throughout the drawings to represent the same parts.

### DETAILED DESCRIPTION OF THE INVENTION

Provided are coatings, coated components, and processes using coated components that do not suffer from drawbacks of the prior art. Embodiments of the present disclosure, for example, in comparison to concepts failing to include one or more of the features disclosed herein, resist chemical attack and degradative loss from a caustic solution, maintain moieties at the surface and/or within the bulk, provide low surface energy and high water contact angles, resist reactivity with caustic species, retain chemistry that provides low surface energy and hydrophobic character, or a combination thereof.

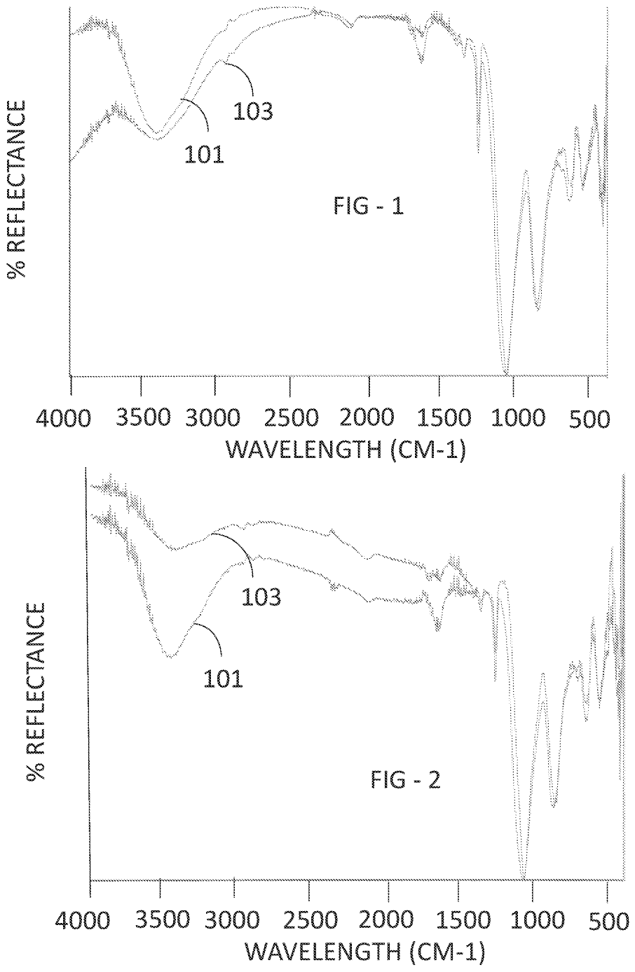

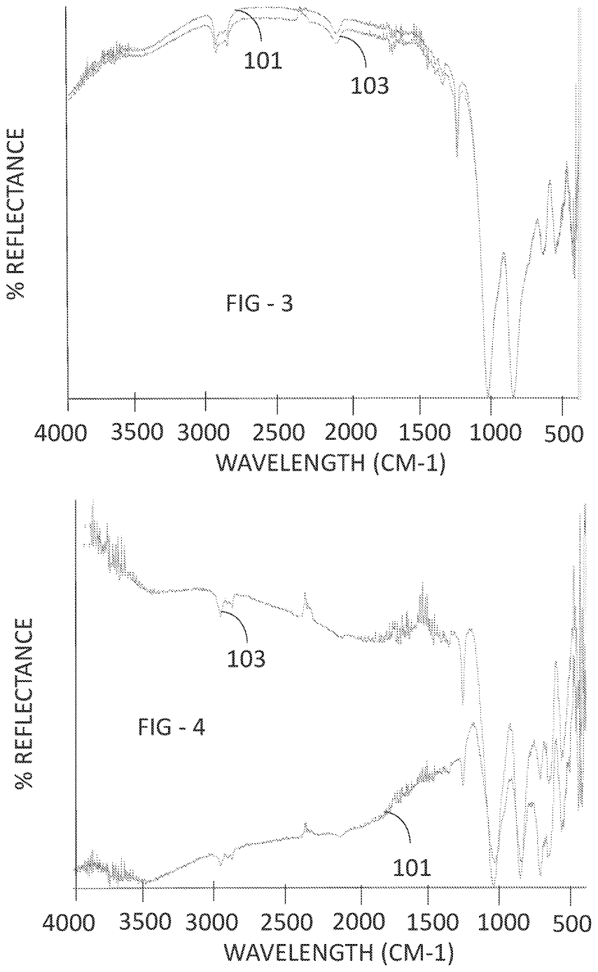

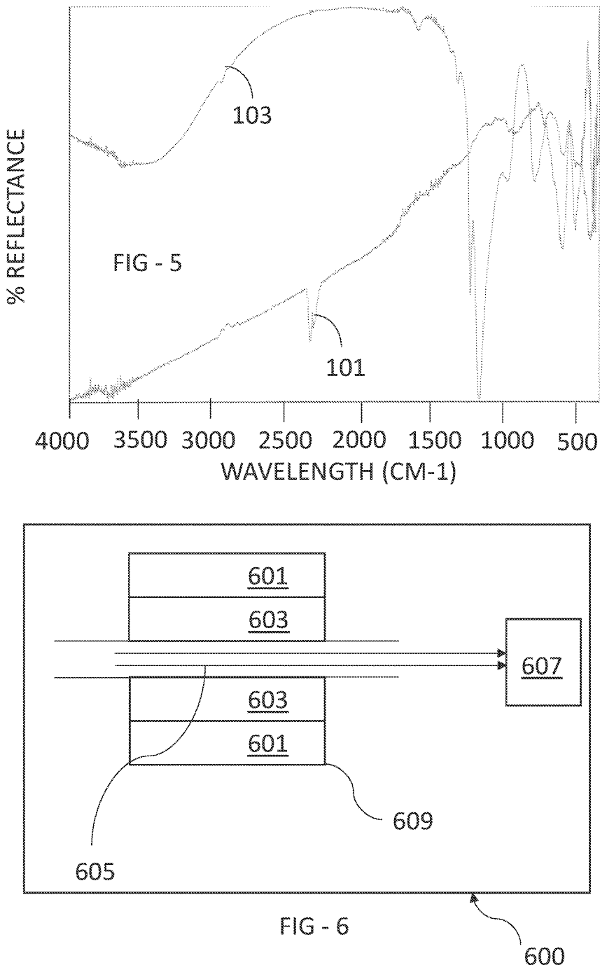

Referring to FIG. 6, according to an embodiment, a coating 603 is on a substrate 601 of a component 609, for example, used in a system 600 for performing a process to produce a product 607. The coating 603 maintains appearance, thickness, and water contact angles after exposure to at least a 20-minute cleaning cycle in an aqueous solution of a caustic salt 605, for example, 5-10% NaOH, by weight/volume or KOH, at elevated temperature (79.44° C.) with ultrasonic agitation. As described in the Examples section below, FIGS. 3 and 4 show FT-IR plots for specific embodiments of the coating 603; FIGS. 1, 2, and 5 show FT-IR plots of comparative coatings.

In response to exposure to the caustic salt 605 (for example, the NaOH, the KOH, or a similar caustic salt), the coating 603 maintains at least 62% of the original contact angle, at least 70% of the original contact angle, at least 80% of the original contact angle, at least 85% of the original contact angle, between 60% and 90% of the original contact angle, between 80% and 90% of the original contact angle, between 85% and 90% of the original contact angle, between 88% and 90% of the original contact angle, or any suitable combination, sub-combination, range, or sub-range therein. Additionally or alternatively, in response to exposure to the caustic salt 605, the coating 603 has a contact angle above 80, above 81, above 82, above 83, above 84, above 85, between 80 and 90, between 80 and 88, between 80 and 87, between 82 and 87, between 85 and 87, or any suitable combination, sub-combination, range, or sub-range therein.

The substrate 601 is any material capable of being processed in a thermal chemical vapor deposition process. Embodiments of the present disclosure include the thermal chemical vapor deposition process operating with cycles of temperature ranges, precursor introduction sequences, pressure ranges, and saturation/soak durations. By having static/pulsed periods (for example, periods where the precursor is heated without flowing through a chemical vapor deposition vessel in an oven), such cycles permit the coating 603 to be applied to simple geometries (for example, having surfaces capable of being coated by line-of-site techniques) and complex geometries (for example, having three-dimensional aspects that are incapable of being coated by line-of-site techniques).

For example, suitable materials are resistant to thermal conditions of greater than 200° C., greater than 300° C., greater than 350° C., greater than 370° C., greater than 380° C., greater than 390° C., greater than 400° C., greater than 410° C., greater than 420° C., greater than 430° C., greater than 440° C., greater than 450° C., greater than 500° C., between 300° C. and 450° C., between 350° C. and 450° C., between 380° C. and 450° C., between 300° C. and 500° C., between 400° C. and 500° C., or any suitable combination, sub-combination, range, or sub-range therein.

In one embodiment, the substrate 601 is stainless steel, for example, a 300-series stainless steel (such as, 316 stainless steel, 316L stainless steel, or 304 stainless steel) or 400-series stainless steel. In another embodiment, the substrate 601 is an aluminum alloy, for example, a 1000-series aluminum alloy, a 3000-series aluminum alloy, a 4000-series aluminum alloy, or a 6000-series aluminum alloy. Other suitable types of materials include Hastelloy®, Inconel®, platinum and platinum alloys, titanium and titanium alloys, and combinations thereof.

The substrate 601 is capable of having any at least partially flexible structure capable of being furled. For example, suitable structures for the substrate 601 include metal sheeting, porous, non-porous, woven cloth, perforated foil, a lattice structure, and combinations thereof. As used herein, the term “furled” and grammatical variations thereof, refers to being rolled or wrapped in a coil-like orientation. Examples of furled objects consistent with the definition herein include metal coils, bolts of fabric, sails wound around masts, wound wire, and window blinds. The term furled is not intended to be limited to tight winding.

To perform the chemical vapor deposition, a precursor fluid is used. The precursor fluid is a liquid or gas (but not a plasma) and imparts chemical constituents to produce the coating 601 within a chemical vapor deposition chamber. The chemical vapor deposition chamber is an enclosed vessel.

The precursor fluid(s) or functionalizer(s) is/are cycled in a single cycle or multiple cycles, for example, with intermediate purges (for example, with inert gases, such as, nitrogen, helium, and/or argon). Suitable numbers of cycles include two cycles, three cycles, four cycles, five cycles, six cycles, seven cycles, eight cycles, nine cycles, ten cycles, eleven cycles, twelve cycles, thirteen cycles, fourteen cycles, fifteen cycles, sixteen cycles, or any suitable combination, sub-combination, range, or sub-range therein.

The precursor fluid is capable of being one or more of the following fluids: silane, silane and ethylene, silane and an oxidizer, dimethylsilane, dimethylsilane and an oxidizer, trimethylsilane, trimethylsilane and an oxidizer, dialkylsilyl dihydride, alkylsilyl trihydride, non-pyrophoric species (for example, dialkylsilyl dihydride and/or alkylsilyl trihydride), thermally-reacted material (for example, carbosilane and/or carboxysilane, such as, amorphous carbosilane and/or amorphous carboxysilane), species capable of a recombination of carbosilyl (disilyl or trisilyl fragments), methyltrimethoxysilane, methyltriethoxysilane, dimethyldimethoxysilane, dimethyldiethoxysilane, trimethylmethoxysilane, trimethylethoxysilane, ammonia, hydrazine, trisilylamine, Bis(tertiary-butylamino)silane, 1,2-bis(dimethylamino)tetramethyldisilane, dichlorosilane, hexachlorodisilane), organofluorotrialkoxysilane, organofluorosilylhydride, organofluoro silyl, fluorinated alkoxysilane, fluoroalkylsilane, fluorosilane, tridecafluoro 1,1,2,2-tetrahydrooctylsilane, (tridecafluoro-1,1,2,2-tetrahydrooctyl) triethoxysilane, triethoxy (3,3,4,4,5,5,6,6,7,7,8,8,8-tridecafluoro-1-octyl) silane, (perfluorohexylethyl) triethoxysilane, silane (3,3,4,4,5,5,6,6,7,7,8,8,9,9,10,10,10-heptadecafluorodecyl) trimethoxy-, or a combination thereof.

In one embodiment, pure (100%) ethylene is used as a functionalizer of the precursor fluid. Alternatively, ethylene has a concentration, by volume, of greater than 50%, greater than 60%, greater than 70%, greater than 80%, greater than 90%, greater than 95%, greater than 99%, between 60% and 100%, between 80% and 100%, between 90% and 100%, or any suitable combination, sub-combination, range, or sub-range therein. In further embodiments, balances of the precursor fluid are argon, krypton, helium, nitrogen, xenon, hydrogen, or a combination thereof.

In one embodiment, the coating 603 is produced with the partial pressures for the fluid being between 10 Torr and 100 Torr, 10 Torr and 50 Torr, 10 Torr and 300 Torr, 200 Torr and 300 Torr, 100 Torr and 1,500 Torr, between 100 Torr and 300 Torr, between 200 Torr and 400 Torr, between 300 Torr and 500 Torr, between 600 Torr and 800 Torr, between 500 Torr and 1,000 Torr, between 500 Torr and 1,500 Torr, between 1,000 Torr and 1,500 Torr, between 500 Torr and 3,000 Torr, between 1,500 Torr and 2,500 Torr, between 1,000 Torr and 3,500 Torr, less than 1,500 Torr, less than 1,000 Torr, less than 500 Torr, less than 300 Torr, or any suitable combination, sub-combination, range, or sub-range therein.

In one embodiment, the coating 603 is produced with the temperature and the pressure being maintained for at least 10 minutes, at least 20 minutes, at least 30 minutes, at least 45 minutes, at least 1 hour, at least 2 hours, at least 3 hours, at least 4 hours, at least 5 hours, at least 7 hours, between 10 minutes and 1 hour, between 20 minutes and 45 minutes, between 4 and 10 hours, between 6 and 8 hours, between 4 and 20 hours, between 10 and 20 hours, or any suitable combination, sub-combination, range, or sub-range therein.

Suitable thicknesses of the coating 603 include between 100 nanometers and 10,000 nanometers, between 100 nanometers and 1,000 nanometers, between 100 nanometers and 800 nanometers, between 200 nanometers and 600 nanometers, between 200 nanometers and 10,000 nanometers, between 500 nanometers and 3,000 nanometers, between 500 nanometers and 2,000 nanometers, between 500 nanometers and 1,000 nanometers, between 1,000 nanometers and 2,000 nanometers, between 1,000 nanometers and 1,500 nanometers, between 1,500 nanometers and 2,000 nanometers, 800 nanometers, 1,200 nanometers, 1,600 nanometers, 1,900 nanometers, or any suitable combination, sub-combination, range, or sub-range therein. Further embodiments include the thicknesses being at any single point on the coating 603, on all portions of the coating 603 (for example, with the range encompassing thickness variation), and/or on regions of the coating 603 (for example, one surface, multiple surfaces, edges/corners, all or some portions incapable of being coated by line-of-site techniques, and/or all or some portions capable of being coated by line-of-site techniques).

Suitable compositions of the coating 603 include the coating 603 being an amorphous silicon coating, a silicon-oxygen-carbon-containing coating, a silicon-nitrogen-containing coating, a silicon-fluorine-carbon-containing coating, or a combination thereof. Further embodiments include the coating 603 having a carbon functionalization.

According to embodiments of the disclosure, the system 600 provides control of an operation selected from the group consisting of industrial processes, energy technology, information technology, consumer electronics, medical diagnostics, illumination technology, transportation technology, communications technology, and combinations thereof.

In another embodiment, the system 600 produces a two-terminal device, a three-terminal device, a four-terminal device, or a combination thereof. In one embodiment, the two-terminal devices is or includes diodes for alternating currents (DIACs), rectifier diodes, Gunn diodes, impact ionization avalanche transit-time diodes (IMPATT diodes), laser diodes, light-emitting diodes, photocells, PIN (P-type, intrinsic, and N-type material) diodes, Schottky diodes, solar cells, Tunnel diodes, Zener diodes, and combinations thereof. In one embodiment, the two-terminal devices is or includes bipolar transistors, Darlington transistors, field-effect transistors, insulated-gate bipolar transistors, silicon-controlled rectifiers, thyristors, triodes for alternating current (TRIACs), unijunction transistors, and combinations thereof.

In one embodiment, the system 600 produces multi-terminal devices, the multi-terminal devices including or being integrated circuits, charge-coupled devices, microprocessors, random-access memory devices, read-only memory devices, and combinations thereof.

In one embodiment, the system 600 products 607 having solid material including a regular, periodic structure of individual atoms bonded together. Additionally or alternatively, in one embodiment, the products 607 are crystalline solid materials, poly-crystalline solid materials, amorphous materials, intrinsic semiconductors, extrinsic semiconductors, or combinations thereof.

In one embodiment, the system 600 produces a semiconductor doped with a negative charge conductor, a positive charge conductor, or both.

In one embodiment, the semiconductor produced by the system 600 is or includes silicon, germanium, carbon, indium antimonide, indium arsenide, indium phosphide, gallium phosphide, gallium antimonide, gallium arsenide, silicon carbide, gallium nitride, silicon germanium, selenium sulfide, and combinations thereof.

### Examples

In a first and second comparative example, a first and second comparative coating are produced from thermal chemical vapor deposition of dimethylsilane (DMS).

In a third and fourth example, consistent with embodiments of the present disclosure, the coatings 603 are produced from thermal chemical vapor deposition of dimethylsilane (DMS) followed by surface functionalization at elevated temperature with pure ethylene. In the third example, the coating 603 is on a mirror-polished (ASTM A480, 400 grit/4-8 microinch roughness) side of the substrate 601. In the fourth example, the coating 603 is on a rough surface side (ASTM A480, 120 grit/40-60 microinch roughness) of the substrate 601. In the third and the fourth example, the substrate 601 is 22-gauge thickness 316 stainless steel.

In a fifth comparative example consistent with U.S. Pat. No. 9,340,880, directed to a “Semiconductor Fabrication Process,” the entirety of which is incorporated by reference, a fifth comparative coating is produced from thermal chemical vapor deposition of dimethylsilane (DMS) followed by thermal oxidation and functionalization using trimethylsilane.

The five coatings are exposed to a 20-minute cleaning cycle in an aqueous solution of 5-10% NaOH, by weight/volume, at elevated temperature (79.44° C.) with ultrasonic agitation. As shown below, water contact angles are obtained before and after the exposure, showing relative stability (or lack thereof):

| Example | Contact Angle (before) | Contact Angle (after) |
|---|---|---|
| 1 (comparative) | 100 | 55 |
| 2 (comparative) | 108 | 59 |
| 3 (exemplary) | 96 | 86 |
| 4 (exemplary) | 133 | 83 |
| 5 (comparative) | 106 | 26 |

The first and second comparative coating show patchy coating loss. The third coating shows no visual change, although contact angle decreases slightly. The fourth coating shows some patchy coating loss. The fifth comparative coating virtually complete coating loss.

FIGS. 1-5 show FT-IR of each example before 101 and after 103 the cleaning cycle, indicating relative stability (or lack thereof).

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A coated article, comprising:
a substrate;
a coating on the substrate;
wherein the coating includes silicon, carbon, and hydrogen;
wherein a post-exposure water contact angle of the coating, after being exposed to ultrasonic agitation for at least 20 minutes using an aqueous solution of a caustic salt, remains above 80 degrees, remains greater than 60% of a pre-exposure water contact angle, or both.

2. The coated article of claim 1, wherein the at least 20 minutes is at a temperature of at least 79° C.

3. The coated article of claim 1, wherein the caustic salt is NaOH.

4. The coated article of claim 1, wherein the caustic salt is KOH.

5. The coated article of claim 1, wherein the caustic salt is at a weight per volume of between 5% and 10%.

6. A system comprising the coated article of claim 1, wherein the system provides a control of an operation selected from the group consisting of industrial processes, energy technology, information technology, consumer electronics, medical diagnostics, illumination technology, transportation technology, communications technology, and combinations thereof.

7. A system comprising the coated article of claim 1, wherein the system produces a two-terminal device, a three-terminal device, a four-terminal device, or a combination thereof.

8. A system comprising the coated article of claim 1, wherein the system produces two-terminal devices, the two-terminal devices being selected from the group consisting of diodes for alternating currents (DIACs), rectifier diodes, Gunn diodes, impact ionization avalanche transit-time diodes (IMPATT diodes), laser diodes, light-emitting diodes, photocells, PIN (P-type, intrinsic, and N-type material) diodes, Schottky diodes, solar cells, Tunnel diodes, Zener diodes, and combinations thereof.

9. A system comprising the coated article of claim 1, wherein the system produces three-terminal devices, the three-terminal devices being selected from the group consisting of bipolar transistors, Darlington transistors, field-effect transistors, insulated-gate bipolar transistors, silicon-controlled rectifiers, thyristors, triodes for alternating current (TRIACs), unijunction transistors, and combinations thereof.

10. A system comprising the coated article of claim 1, wherein the system produces multi-terminal devices, the multi-terminal devices being selected from the group consisting of integrated circuits, charge-coupled devices, microprocessors, random-access memory devices, read-only memory devices, and combinations thereof.

11. A system comprising the coated article of claim 1, wherein the system produces products having solid material including a regular, periodic structure of individual atoms bonded together.

12. A system comprising the coated article of claim 1, wherein the system produces a crystalline solid material.

13. A system comprising the coated article of claim 1, wherein the system produces a poly-crystalline solid material.

14. A system comprising the coated article of claim 1, wherein the system produces an amorphous material.

15. A system comprising the coated article of claim 1, wherein the system produces an intrinsic semiconductor.

16. A system comprising the coated article of claim 1, wherein the system produces an extrinsic semiconductor.

17. A system comprising the coated article of claim 1, wherein the system produces a semiconductor doped with a negative charge conductor, a positive charge conductor, or both.

18. A system comprising the coated article of claim 1, wherein the system produces a semiconductor selected from the group consisting of silicon, germanium, carbon, indium antimonide, indium arsenide, indium phosphide, gallium phosphide, gallium antimonide, gallium arsenide, silicon carbide, gallium nitride, silicon germanium, selenium sulfide, and combinations thereof.

19. A process of applying the coating on the substrate of claim 1.

20. A coated article, comprising:
a substrate;
a coating on the substrate;
wherein the coating includes silicon, carbon, and hydrogen;
wherein a post-exposure water contact angle of the coating, after being exposed to ultrasonic agitation at a temperature of at least 79° C. using an aqueous solution of a caustic salt, remains above 80 degrees, remains greater than 60% of a pre-exposure water contact angle, or both.
